(19) United States
(12) Patent Application Publication
(10) Pub. No.: US 2026/0022228 A1
(43) Pub. Date: Jan. 22, 2026

(54) Multifunctional Composite Material for Enhanced Durability, Antimicrobial Properties, Thermal Management, and Electromagnetic Shielding

(71) Applicant: Nicolas Brian Quiroz, Clovis, CA (US)

(72) Inventor: Nicolas Brian Quiroz, Clovis, CA (US)

(21) Appl. No.: 18/776,422

(22) Filed: Jul. 18, 2024

(51) Int. Cl. C08K 3/08; A43B 13/02; C08K 3/22; C08K 3/36; C08L 21/00; H05K 9/00

(52) U.S. Cl. CPC C08K 3/08; C08K 3/22; C08K 3/36; C08L 21/00; H05K 9/0081; A43B 13/026; C08K 2003/085; C08K 2003/2275; C08K 2201/001; C08K 2201/011; C08K 2201/014

(57) ABSTRACT

This invention relates to a composite material comprising rubber, silica, nano copper, and magnetite, designed for use in various applications including shoe soles, medical products, military equipment, consumer electronics, robotics, space exploration, automotive components, and electromagnetic shielding for electric vehicle (EV) batteries. The material is theoretically designed to offer enhanced durability, improved grip, antimicrobial properties, thermal conductivity, and electromagnetic shielding capabilities.

### DETAILED DESCRIPTION OF THE PREFERRED EMBODIMENT

### 1. Composition

Rubber Matrix: Forms the base of the composite, providing flexibility, elasticity, and impact resistance. Rubber's inherent properties make it an ideal matrix material for various applications.
Silica (SiO2): Added to the rubber matrix in a proportion ranging from 5% to 30% by weight. Silica enhances abrasion resistance, strength, and thermal stability. It also improves the overall durability of the composite material.
Nano Copper (Cu): Incorporated into the rubber matrix in a proportion ranging from 1% to 10% by weight. The nano copper particles, with a size range of 10-100 nm, provide antimicrobial properties and contribute to the thermal conductivity of the composite. Copper's antimicrobial nature helps reduce bacterial growth and odor, while its thermal properties aid in heat dissipation.
Magnetite (Fe3O4): Included in the rubber matrix in a proportion ranging from 1% to 10% by weight. Magnetite imparts magnetic properties and aids in electromagnetic shielding and potential energy harvesting. Its inclusion enhances the composite's ability to shield against electromagnetic interference.

### 2. Manufacturing Process

Mixing: The rubber, silica, nano copper, and magnetite are mixed thoroughly to ensure even distribution. This can be achieved using standard industrial mixers suitable for composite materials. The mixing process is critical to achieving a uniform distribution of the components, which is essential for consistent performance.
Vulcanization: The mixed composite is subjected to vulcanization, a chemical process for converting rubber into more durable materials via the addition of sulfur or other equivalent curatives or accelerators. Vulcanization enhances the material's strength and elasticity.
Molding: The vulcanized composite material is then molded into the desired shape using appropriate molds and techniques. This step involves shaping the material into its final form for specific applications.
Curing: The molded composite is then cured under controlled conditions to achieve the final product with desired mechanical and physical properties. Curing ensures the material reaches its optimal performance characteristics.

### 3. Properties and Benefits

Enhanced Durability: The addition of silica significantly increases the wear resistance of the composite material, making it more durable for applications subjected to high stress and wear.
Improved Grip: Silica enhances the grip of the material on various surfaces, reducing the risk of slips and falls, while also providing excellent abrasion resistance. This is particularly beneficial for footwear and safety gear.
Antimicrobial Properties: Nano copper is known for its antimicrobial properties, which help in reducing odor and bacterial growth, ensuring hygiene and comfort. This makes the material suitable for medical devices and consumer products.
Thermal Conductivity: The presence of nano copper improves the thermal conductivity of the material, potentially providing better temperature regulation. This is important for applications in electronics and automotive components.
Magnetic and Electromagnetic Properties: Magnetite contributes to the magnetic properties of the composite, which aids in electromagnetic shielding and potential energy harvesting. This makes the material suitable for military and space applications.

### 4. Inventive Steps and Non-Obviousness

Combination of Materials: The combination of rubber, silica, nano copper, and magnetite in a single composite material is novel and non-obvious. The specific ratios, processing methods, and resulting properties of the composite are not suggested by prior art.
Synergistic Effects: The integration of these materials results in synergistic effects that enhance the performance characteristics of the composite. For instance, the addition of nano copper not only provides antimicrobial properties but also significantly improves the thermal conductivity of the rubber matrix. This dual functionality is not apparent from the prior art involving rubber composites.
Multifunctionality: The composite material is unique in providing multiple functionalities simultaneously, including durability, grip, antimicrobial properties, thermal management, and electromagnetic shielding.
Specific Applications and Integration: The composite material's ability to be molded into various forms while maintaining its multifunctional properties is non-obvious. For example, its application in shoe soles not only improves durability and grip but also incorporates antimicrobial properties and thermal management, which are novel and non-obvious improvements over traditional materials used in footwear.
Tailored Proportions and Processing: The invention involves specific proportions and processing techniques to ensure that the material properties are optimized for different applications. The innovative steps include determining the optimal ratios of rubber, silica, nano copper, and magnetite to achieve the desired properties, developing proprietary processing methods to ensure uniform distribution and bonding of the components within the rubber matrix, and tailoring the curing and vulcanization processes to enhance the composite's mechanical and thermal properties.

### 5. Experimental Results

### Theoretical Benefits

Durability and Flexibility: Based on the known properties of rubber and silica, the composite material is expected to provide enhanced durability and flexibility. Silica's role in increasing abrasion resistance and rubber's inherent flexibility suggests significant improvements in wear resistance and comfort.
Antimicrobial Properties: Nano copper is widely recognized for its antimicrobial properties. Incorporating nano copper into the composite is expected to reduce bacterial growth and odors, maintaining hygiene in applications such as footwear and medical devices.
Thermal Management: The high thermal conductivity of nano copper suggests that the composite material will have improved heat dissipation capabilities. This is particularly beneficial for applications in consumer electronics and automotive components where thermal management is crucial.
Electromagnetic Shielding: Magnetite's magnetic properties indicate that the composite material will provide effective electromagnetic interference (EMI) shielding. This is beneficial for protecting sensitive electronic components in various applications.

### Planned Testing

To verify the theoretical benefits, the following tests are planned:
Durability Testing: Conduct wear and abrasion resistance tests to quantify the durability improvements of the composite material compared to standard rubber.
Antimicrobial Testing: Perform microbial growth assays to measure the effectiveness of nano copper in reducing bacterial proliferation on the composite material.
Thermal Conductivity Testing: Measure the thermal conductivity of the composite material to confirm its heat dissipation capabilities.
Electromagnetic Shielding Testing: Test the material's ability to shield against electromagnetic interference using standard EMI testing protocols.

### TECHNICAL FIELD

This invention relates to the field of composite materials and more specifically to a novel composite material with multifunctional properties suitable for diverse industrial, medical, technological, and automotive applications.

### BACKGROUND ART

Existing materials used in various applications offer specific benefits but often lack multifunctionality. Traditional materials like rubber and synthetic polymers provide adequate durability and flexibility but do not effectively address issues such as bacterial growth, thermal management, and electromagnetic interference. By combining rubber, silica, nano copper, and magnetite, this composite material aims to enhance performance across multiple applications, providing improved durability, antimicrobial properties, thermal management, and electromagnetic shielding.

### DETAILED DESCRIPTION OF SPECIFIC APPLICATIONS

### Shoe Soles

Durability and Flexibility: The combination of rubber and silica provides a durable yet flexible sole that can withstand high wear and tear, making it ideal for everyday use and athletic footwear.
Grip and Abrasion Resistance: Silica enhances the sole's grip on various surfaces, reducing the risk of slips and falls, while also providing excellent abrasion resistance.
Antimicrobial Properties: Nano copper's antimicrobial properties help in reducing odor and bacterial growth, ensuring hygiene and comfort.
Energy Absorption and Comfort: The material's flexibility allows for effective energy absorption, reducing foot fatigue and enhancing overall comfort.

### Medical Devices

Antimicrobial Surfaces: Ideal for medical devices and equipment, the composite material's antimicrobial properties reduce the risk of infections and maintain hygiene.
Flexible and Durable Components: Used in wearable medical devices, the material provides flexibility and durability, ensuring patient comfort and device reliability.

### Military Applications

Protective Gear: The composite material can be used to manufacture durable and lightweight protective gear, such as helmets and body armor, providing enhanced protection without compromising mobility.
Footwear: Military boots made from this composite offer superior durability, comfort, and antimicrobial properties, essential for long-term use in various environments.
Electromagnetic Shielding: Magnetite's properties enable the creation of materials that shield sensitive military electronics from electromagnetic interference (EMI), ensuring operational security.

### Robotics

Artificial Muscles: The flexibility and durability of the composite make it suitable for creating artificial muscles in soft robotics, providing smooth and lifelike movements.
Robotic Casings and Components: Durable and lightweight casings for robots can be made from this composite, protecting internal components while maintaining operational efficiency.

### Space Exploration

Thermal Protection Systems: The high thermal resistance of silica and the thermal conductivity of nano copper can be utilized in thermal protection systems for spacecraft, protecting them during re-entry and extreme conditions.
Radiation Shielding: Magnetite's radiation shielding properties can protect sensitive electronic equipment and astronauts from harmful space radiation.

### Tesla/EV's

Battery and Powertrain Thermal Management: The composite's thermal conductivity can improve heat dissipation in Tesla's batteries and powertrains, enhancing performance and safety.
Durable Automotive Components: The material can be used to create durable, lightweight components for Tesla vehicles, improving efficiency and reducing maintenance needs.
Electromagnetic Shielding for EV Batteries: The composite material can be used to line the enclosures of EV batteries, providing electromagnetic shielding to protect passengers from potential radiation emitted by the batteries.

### Qualcomm

Advanced Electronics and Wearables: The composite can be used to develop durable and thermally efficient casings for Qualcomm's processors and chipsets.
EMI Shielding: Magnetite's properties can provide effective electromagnetic shielding for electronic devices, ensuring signal integrity and reducing interference.

### INDUSTRIAL APPLICABILITY

The described composite material can be utilized in the manufacturing of high-performance products across various industries, including footwear, medical products, sporting goods, consumer electronics, construction materials, automotive components, robotics, space exploration, and military applications.

### CONCLUSION

The novel composite material of rubber, silica, nano copper, and magnetite offers a versatile platform with applications across various industries. Its unique properties make it suitable for enhancing the performance and durability of products in footwear, consumer electronics, medical devices, military equipment, robotics, space exploration, and automotive components, including electromagnetic shielding for EV batteries. Further research and development will focus on experimentally validating these benefits to support the claims made in this patent application.

1. A composite material comprising rubber, silica, nano copper, and magnetite, characterized by its potential for enhanced durability, flexibility, antimicrobial properties, thermal conductivity, and electromagnetic shielding capabilities.

2. The composite material of claim 1, wherein the silica content ranges from 5% to 30% by weight.

3. The composite material of claim 1, wherein the nano copper content ranges from 1% to 10% by weight.

4. The composite material of claim 1, wherein the magnetite content ranges from 1% to 10% by weight.

5. The composite material of claim 1, wherein the rubber matrix provides flexibility and impact resistance.

6. The composite material of claim 1, wherein the silica enhances abrasion resistance and strength.

7. The composite material of claim 1, wherein the nano copper imparts antimicrobial properties and improves thermal conductivity.

8. The composite material of claim 1, wherein the magnetite contributes to electromagnetic shielding and magnetic properties.

9. A method of manufacturing the composite material of claim 1, comprising mixing rubber, silica, nano copper, and magnetite to achieve uniform distribution, followed by vulcanization and molding into the desired shape.

10. The composite material of claim 1, used in the manufacture of shoe soles for improved durability, grip, and antimicrobial properties.

11. The composite material of claim 1, used in medical devices for flexible, durable, and antimicrobial components.

12. The composite material of claim 1, used in consumer electronics for durable casings and improved thermal management.

13. The composite material of claim 1, used in military applications for protective gear and electromagnetic shielding.

14. The composite material of claim 1, used in robotics for flexible actuators and durable casings.

15. The composite material of claim 1, used in space exploration for thermal protection and radiation shielding.

16. The composite material of claim 1, used in automotive components for battery and powertrain thermal management and electromagnetic shielding for EV batteries.

17. The composite material of claim 1, used in consumer electronics for durable casings, thermal management solutions, and EMI shielding.
